(19) United States
(12) Patent Application Publication
(10) Pub. No.: US 2026/0010080 A1
(43) Pub. Date: Jan. 8, 2026

(54) MEASURING MODULE FOR DETERMINING THE POSITION OF A COMPONENT IN AN OPTICAL SYSTEM FOR MICROLITHOGRAPHY

(71) Applicant: Carl Zeiss SMT GmbH, Oberkochen (DE)

(72) Inventors: Klaus THURNER, Neresheim (DE); Matthias MANGER, Aalen (DE); Rafael MARANGONI, Schwaebisch Gmuend (DE)

(21) Appl. No.: 19/322,913

(22) Filed: Sep. 9, 2025

Related U.S. Application Data
(63) Continuation of application No. PCT/EP2024/056145, filed on Mar. 8, 2024.

(30) Foreign Application Priority Data
Mar. 16, 2023 (DE) 10 2023 202 412.8

(51) Int. Cl. G03F 7/00; G01B 11/14

(52) U.S. Cl. CPC G03F 7/70591; G01B 11/14; G03F 7/70316; G03F 7/7085; G03F 7/70891; G03F 7/709

(57) ABSTRACT

A measuring module for determining the position of a component in a microlithographic optical system comprises: a first optical resonator for distance measurement by irradiating a first measurement target associated with the component with a first measurement beam; and a second optical resonator for distance measurement by irradiating a second measurement target associated with the component with a second measurement beam. The optical resonators are configured to radiate the two measurement beams onto the corresponding measurement target from different directions.

### CROSS-REFERENCE TO RELATED APPLICATIONS

The present application is a continuation of, and claims benefit under 35 USC 120 to, international application No. PCT/EP2024/056145, filed Mar. 8, 2024, which claims benefit under 35 USC 119 of German Application No. 10 2023 202 412.8, filed Mar. 16, 2023. The entire disclosure of each of these applications is incorporated by reference herein.

### FIELD

The disclosure relates to a measuring module for determining the position of a component in a microlithographic optical system, a measuring arrangement having multiple such measuring modules, and a projection exposure apparatus having at least one such measuring module.

### BACKGROUND

Microlithography is used to produce microstructured components, such as integrated circuits or LCDs. This is implemented using a so-called projection exposure apparatus, which comprises an illumination device and a projection lens. In this context, the image of a mask situated on a reticle and illuminated by way of the illumination device is projected by way of the projection lens onto a substrate (e.g. a silicon wafer) coated with a light-sensitive layer (photoresist) and arranged in the image plane of the projection lens, in order to transfer the mask structure to the light-sensitive coating of the substrate.

During operation of such projection lenses, during which mask and wafer are usually moved relative to one another in a scanning process, the positions of the mirrors, some of which are movable in all six degrees of freedom, are set and maintained with relatively high accuracy both with respect to one another and also with respect to mask and/or wafer in order to avoid or at least reduce aberrations and accompanying impairments of the imaging result. This determination of position may involve length measurement accuracies in the order of picometers (pm) over a path length of 1 meter, for example in EUV lithography.

Various approaches for measuring the position of the individual lens mirrors and also of the wafer or the wafer stage and the reticle plane are known. Besides interferometric measurement arrangements, frequency-based position measurement using an optical resonator is also known. A set-up used in DE 10 2012 212 663 A1 to this end comprises a resonator in the form of a Fabry-Perot resonator with two resonator mirrors, of which the first resonator mirror is secured to a reference element in the form of a measurement frame fixedly connected to the housing of the projection lens of the projection exposure apparatus and the second resonator mirror (as what is known as the “measurement target”) is secured to an EUV mirror to be measured with regard to the position thereof. The actual distance measuring apparatus comprises a radiation source, which is tunable with respect to its optical frequency and which creates input coupling radiation that passes through a beam splitter and is input coupled into the optical resonator. In that case, the radiation source is controlled by a coupling device in such a way that the optical frequency of the radiation source is tuned to the resonant frequency of the optical resonator and is thus coupled to the resonant frequency. Input coupling radiation output coupled via a beam splitter is analyzed using an optical frequency measuring device which can comprise, e.g., a frequency comb generator for highly accurate determination of the absolute frequency. If the position of the EUV mirror changes in the direction of extent of the resonator, then together with the distance between the resonator mirrors the resonant frequency of the optical resonator also changes and hence—owing to the coupling of the frequency of the tunable radiation source to the resonant frequency of the resonator—the optical frequency of the input coupling radiation changes as well, which is in turn registered directly by the frequency measurement device.

Should the position of the component be determined very meaningfully, multiple measuring modules are often used so that the position can be measured in multiple coordinate directions. For example, six measuring modules are used in DE 10 2018 208 147 A1 for the purpose of determining the position in all six rigid-body degrees of freedom, i.e. displacements in the directions of the x-, y- and z-axes and tilts about the x-, y- and z-axes. However, the installation space in the region of the component to be measured often does not suffice for the installation of a sufficient number of measuring modules, or the measuring modules are installed with unfavorable beam angles such that the measuring accuracy is adversely affected. Furthermore, reference should be made to US2022/0050043A1 and US2018/0306696A1.

### SUMMARY

The disclosure seeks to provide a measuring module whereby the aforementioned problems are solved, and positions can be determined very meaningfully even in the event of tight installation space conditions.

In an aspect, the disclosure provides a measuring module for determining the position of a component in a microlithographic optical system. The measuring module comprises a first optical resonator for distance measurement by irradiating a first measurement target associated with the component with a first measurement beam, and a second optical resonator for distance measurement by irradiating a second measurement target associated with the component with a second measurement beam. The optical resonators are configured to radiate the two measurement beams onto the corresponding measurement target from different directions.

In this text, an optical resonator should be understood to mean an arrangement of mirrors that serves to reflect light back and forth as often as possible. According to an embodiment, the optical resonators of the measuring module are each configured to ensure that measurement radiation radiated into the relevant optical resonator still has at least 90%, such as at least 99%, of the radiated intensity after at least five passes, such as after at least ten passes, through the optical resonator. According to a further embodiment, the optical resonators of the measuring module are each configured to reflect the radiated-in measurement radiation back and forth multiple times (for example at least 10 times, at least 100 times, at least 1000 times) before the measurement radiation leaves the optical resonator again, wherein leaving the optical resonator should be understood to mean that the intensity of a measurement radiation remaining in the resonator is less than 50% of the intensity of the measurement radiation radiated in. According to a further embodiment, the optical resonators of the measuring module each have a finesse of at least 100, such as at least 1000.

For example, the component to be measured could be a mirror in an exposure beam path of a microlithographic projection exposure apparatus, the position of the mirror possibly changing, for instance on account of a misalignment process, during the operation of the projection exposure apparatus. Therefore, the component may also be referred to as a movable component. The respective distance measurement is taken between the respective measurement target and a respective reference element. On account of the measurement targets being irradiated from different directions, the position of the component can be determined in at least two dimensions. In this case, the reference element and the measurement target of the respective optical resonator may be formed by two resonator mirrors that enclose a resonator cavity of the optical resonator. Each of the resonators comprises a resonator cavity, and so the measuring module may also be referred to as a measuring module with a multiple cavity. According to an embodiment, the directions of the two measurement beams deviate from each other by at least 30°.

As a result of the disclosure providing for the integration of two optical resonators into a single measuring module for the purpose of a distance measurement with differently aligned measurement beams, the measuring module may determine a position in at least two spatial coordinate directions, i.e. determine a position meaningfully, even in the event of tight installation space conditions in the region of the component to be measured. For example, position is determined more meaningfully than in the case where a measuring module with only one optical resonator is used. Furthermore, determining the position of the component highly accurately in all six rigid-body degrees of freedom, for instance, involves fewer measuring module modules when using the measuring module according to the disclosure rather than when using a conventional measuring module with only one optical resonator.

By integrating the two optical resonators into the measuring module, the measurement axes that define the directions of the measurement beams may already be adjusted with respect to each other before the measuring module is installed in the microlithographic optical system. This can eliminate adjusting the measurement axes post installation, as this can be very complex or may not be realizable with the desired accuracy should the installation space be tight in the region of the component to be measured. Furthermore, the integration of the two optical resonators into the measuring module may better ensure that the adjustment of the measurement axes remains stable during operation, i.e. that readjustment is rendered unnecessary or at least used less often.

According to an embodiment, the two measurement targets are differently oriented portions of a contiguous measurement object. According to an embodiment variant, the two measurement targets are tilted with respect to each other by at least 80°, such as oriented perpendicular to each other.

According to an embodiment, at least one of the measurement targets is a resonator mirror of the relevant optical resonator.

According to an embodiment, at least one of the optical resonators comprises a deflection element for changing the direction of a beam path within the relevant resonator. The deflection element may be a mirror element, for example. Alternatively, it may be configured as a prism. Such a prism can be advantageous when there is total-internal reflection occurring therein, because there is no loss of the measurement radiation.

According to an embodiment, the change of direction is in an angular range between 30° and 150°, such as between 80° and 100°. This means that the deflection element is configured such that the direction of the measurement radiation radiated thereon is deflected through an angle between 30° and 150°.

According to an embodiment, the deflection element is configured to deflect the measurement radiation from an input beam path originating from an input coupling mirror of the relevant resonator into the relevant measurement beam.

According to an embodiment, respective input beam paths of the two optical resonators, which originate from a respective input coupling mirror of the relevant resonator, are arranged parallel to each other or deviate from the parallel arrangement by no more than 10°.

According to an embodiment, each of the resonators is associated with a waveguide for supplying measurement radiation. According to an embodiment variant, the waveguides each connect a measurement radiation unit to the relevant resonator, with the measurement radiation unit providing and evaluating the measurement radiation for the respective resonator.

According to an embodiment, the optical system is a microlithographic projection exposure apparatus, such as for EUV microlithography.

According to an embodiment, the measuring module is configured to perform a frequency-based length measurement on each of the two optical resonators.

To this end, the measuring module according to an embodiment variant comprises a radiation source for each of the two optical resonators, wherein the radiation sources are tunable with respect to their optical frequency for the purpose of generating the respective measurement beam. The measuring module can comprise a coupling module for each of the optical resonators, wherein the coupling module is configured to couple the optical frequency of the relevant radiation source to a resonant frequency of the relevant optical resonator. Coupling the optical frequency to the resonant frequency should be understood to mean that the optical frequency is aligned with the resonant frequency. In other words, the optical frequency of the relevant radiation source is matched to the resonant frequency of the relevant optical resonator, i.e. the optical frequency follows the resonant frequency.

The measuring module can also comprise a respective frequency measuring device for measuring the optical frequency of the respective coupled radiation source. The length of the optical resonator is functionally dependent on the measured optical frequency, i.e. the current length of the optical resonator can be determined from the measured optical frequency. In other words, the length of the optical resonator is encoded as the optical frequency of the tunable radiation source. The measuring module can also comprise a respective computing unit for determining the length of the respective optical resonator from the measured optical frequency and hence determining the distance between a respective input coupling mirror of the relevant optical resonator and the relevant measurement target.

According to an embodiment of the measuring module, the two measurement beams are aligned such that their extensions through the respective measurement target intersect each other. The beam axes of the extended measurement beams can even intersect at a point and/or in a spatial element which comprises at most half, such as a quarter, of the extent of the spatial intersection volume of the extended measurement beams.

In an aspect, the disclosure provides a measuring module for determining the position of a component in a microlithographic optical system, having an optical resonator for distance measurement by irradiating a measurement target associated with the component, wherein the resonator comprises a deflection element for changing the direction of a beam path within the resonator by an angle between 30° and 150°, such as between 80° and 100°.

In an aspect, the disclosure provides a measuring arrangement for determining the position of a component in a microlithographic optical system, comprising at least three measuring modules in any of the aforementioned embodiments or embodiment variants, wherein the measurement targets associated with the respective measuring module are arranged on a respective measurement object and the measurement objects are assigned to different measurement locations on the component to be measured.

According to an embodiment of the measuring arrangement, the directions of three of the measurement beams generated by the measuring modules form linearly independent vectors.

According to an embodiment, the measurement locations assigned to the measurement objects define a measurement plane, at least one of the measurement beams generated by the measuring modules is oriented transversely to the plane and at least two of the measurement beams generated by the measuring modules have different directions, each oriented substantially parallel to the plane. In this context, “substantially parallel” means a maximum deviation of +/−10°, such as of +/−5° from the exact parallel arrangement.

According to an embodiment, the measurement locations assigned to the measurement objects define a measurement plane, and at least three of the measurement beams generated by the measuring modules are oriented transversely to the measurement plane.

According to an embodiment, the locations assigned to the measurement objects form an isosceles triangle in the measurement plane. In this case, at least two of the measurement beams generated by the measuring modules are oriented in the direction of the axis of symmetry of the isosceles triangle, at least one of the measurement beams is oriented transversely to the axis of symmetry in the plane, and at least three of the measurement beams are oriented transversely to the measurement plane. For example, the locations assigned to the measurement objects are located in the xy-plane, and the axis of symmetry of the isosceles triangle is aligned parallel to the y-axis. In that case, according to the aforementioned embodiment, two of the measurement beams are aligned in the y-direction, one measurement beam is aligned in the x-direction and three measurement beams are aligned in the z-direction.

In an aspect, the disclosure provides a microlithographic projection exposure apparatus. The apparatus comprises at least one component and at least one measuring module according to any of the aforementioned embodiments or embodiment variants or a measuring arrangement according to any of the aforementioned embodiments or embodiment variants for determining the position of the component.

According to an embodiment of the projection exposure apparatus, the component to be measured is a mirror in an exposure beam path of the projection exposure apparatus, wherein the measuring module is configured to measure vibrations of the mirror. According to an embodiment variant, the mirror is part of a projection lens of the projection exposure apparatus, or alternatively of the illumination system.

According to an embodiment, the projection exposure apparatus is designed for operation with EUV exposure radiation.

According to an embodiment of the projection exposure apparatus, the component to be measured is a mirror in an exposure beam path of the projection exposure apparatus, wherein the projection exposure apparatus furthermore comprises a cooling device for the mirror via flowing cooling liquid, and the measuring module is configured to measure vibrations of the mirror generated by the cooling process. According to an embodiment variant, the cooling fluid flows through the mirror; alternatively, a flow of the cooling fluid onto the back side of the mirror is also conceivable.

The features specified in relation to the aforementioned embodiments, exemplary embodiments and embodiment variants, etc., of the projection exposure apparatus according to the disclosure are explained in the description of the figures and the claims. The individual features may be implemented, either separately or in combination, as embodiments of the disclosure. Furthermore, they may describe embodiments that are independently protectable and protection for which is claimed only during or after pendency of the application, as the case may be.

### BRIEF DESCRIPTION OF THE DRAWINGS

Various features and embodiments are described in the following detailed description of exemplary embodiments drawings, in which:

FIG. 1 shows an embodiment of a measuring module for determining the position of a component in a microlithographic projection exposure apparatus;

FIG. 2 shows a plan view of a back side of a mirror that serves as the component to be measured and is part of the projection exposure apparatus having a measuring arrangement that comprises three measuring modules of the type shown in FIG. 1;

FIG. 3 shows a respective sectional view of the measuring modules depicted in FIG. 2;

FIG. 4 shows an embodiment of a measuring module for determining the position of a component in a microlithographic projection exposure apparatus;

FIG. 5 shows a detailed view of a measurement radiation unit of the measuring module;

FIG. 6 shows an embodiment of a projection exposure apparatus for EUV microlithography; and

FIG. 7 shows an enlarged detailed view of the projection exposure apparatus according to FIG. 6 in the region of a mirror of a projection lens with a measuring arrangement according to FIG. 2 integrated therein.

### DETAILED DESCRIPTION OF EXEMPLARY EMBODIMENTS

In the exemplary embodiments or embodiments or variant embodiments described below, elements that are functionally or structurally similar to one another are provided with the same or similar reference signs as far as possible. Therefore, for understanding the features of the individual elements of a specific exemplary embodiment, reference should be made to the description of other exemplary embodiments or the general description of the disclosure.

In order to facilitate the description, FIGS. 2, 3, 4, 6 and 7 of the drawing indicate a Cartesian XYZ-coordinate system, from which the respective positional relationship of the components illustrated in the figures is evident. In FIG. 2, the Z-direction runs perpendicular and into the plane of the drawing, the X-direction runs to the left, and the Y-direction runs upwardly.

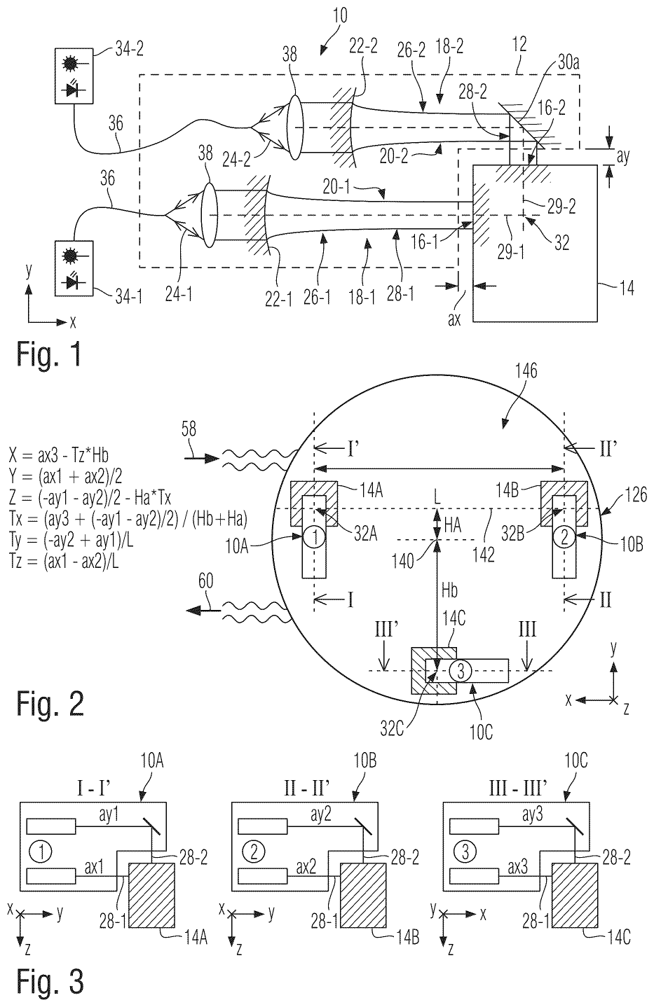

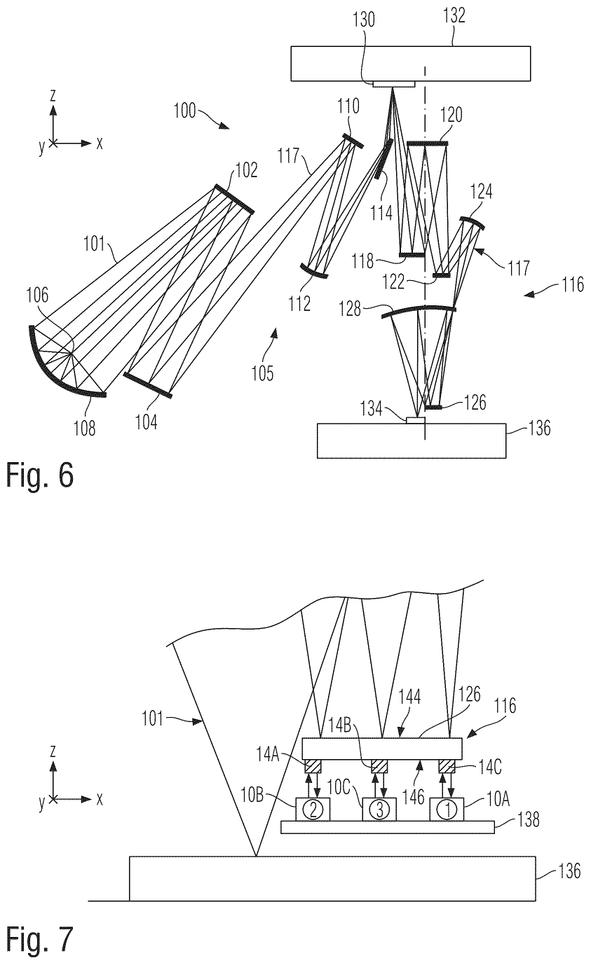

FIG. 1 depicts an embodiment of a measuring module 10 for determining the position of a component in a microlithographic optical system. FIG. 6 illustrates, in a simplified representation, such an optical system in the form of a microlithographic projection exposure apparatus 100, which will be described in more detail later on in the text. A mirror 126 of a projection lens 116 of the projection exposure apparatus 100 serves as the aforementioned component to be measured. The position of this component may change during operation of the projection exposure apparatus 100, and the component may therefore also be referred to as a movable component.

The measuring module 10 according to FIG. 1 comprises a measuring head 12 and a measurement object 14, which comprises two measurement targets 16-1 and 16-2 in the form of reflective surfaces of the measurement object 14. The measurement object 14 is cuboid in the embodiment shown, wherein the reflective surfaces serving as measurement targets 16-1 and 16-2 are oriented perpendicular to each other; to be precise, the first measurement target 16-1 is oriented in the negative x-direction and the second measurement target 16-2 is oriented in the positive y-direction of a xy-coordinate system of the measuring module 10. At this point, attention should be drawn to the fact that the xy-coordinate system of the measuring module 10 specified in FIG. 1 differs from the XYZ-coordinate system contained in FIGS. 2, 3, 4, 6 and 7. In other words, the two measurement targets 16-1 and 16-2 are differently oriented portions of a contiguous measurement object 14.

The measurement object 14 is attached to the back side of the mirror 126 that serves as a component to be measured, i.e. the two measurement targets 16-1 and 16-2 are also attached to the component to be measured and thus associated with the component. To determine the position of the mirror 126, the measuring module 10 is used to determine the distance between the measuring head 12 and the measurement object 14 in the x and y-directions; in more detail, a distance ax between the measuring head 12 and the first measurement target 16-1 in the x-direction and a distance ay between the measuring head 12 and the second measurement target 16-2 in the y-direction are determined, as described in detail below.

The measuring module 10 comprises two optical resonators 18-1 and 18-2. The first optical resonator 18-1 comprises a resonator cavity 20-1 that is enclosed by two resonator mirrors of the resonator 18-1. In this case, the first resonator mirror is formed by an input coupling mirror 22-1, through which a first measurement radiation 24-1 is radiated into the resonator cavity 20-1. The second resonator mirror is formed by the first measurement target 16-1.

The input coupling mirror 22-1 has a curved mirror surface, while the first measurement target 16-1 is formed by a plane mirror surface. The measurement radiation 24 in the resonator cavity 20-1 thus forms a Gaussian beam, the waist of which is located on the mirror surface of the measurement target 16-1. The beam path of the measurement radiation 24-1 emanating from the input coupling mirror 22-1, i.e. the first portion of the Gaussian beam, is also referred to as the input beam path 26-1 of the first optical resonator 18-1. The portion of the Gaussian beam incident on the measurement target 16-1 is also referred to as measurement beam 28-1.

The second optical resonator 18-2 of the measuring module 10 comprises a resonator cavity 20-2, which is enclosed by two resonator mirrors of the resonator 18-2, and a deflection element in the form of a deflection mirror 30a. The first resonator mirror is formed by an input coupling mirror 22-2, through which a second measurement radiation 24-2 is radiated into the resonator cavity 20-2. The deflection element 30a serves to bring about a change in direction of the measurement radiation 24-2 through 90°. There may also be a change in direction through other angles in alternative embodiments, but these angles should be located in an angular range between 30° and 150°, such as between 80° and 100°. In other words, the deflection mirror 30a deflects the measurement radiation 24-2 coming from the input coupling mirror 22-1 through 90°. The deflected measurement radiation is subsequently incident on the second measurement target 16-2 perpendicularly as measurement beam 28-2.

The second measurement target 16-2 forms the second resonator mirror of the optical resonator 18-2. The input coupling mirror 22-2 has a curved mirror surface, while the second measurement target 16-2 represents a plane mirror surface. In a manner analogous to the measurement radiation 24-1 in the first resonator 18-1, the measurement radiation 24-2 thus forms a Gaussian beam, the waist of which is located on the mirror surface of the second measurement target 16-2. The beam path of the measurement radiation 24-2 emanating from the input coupling mirror 22-2 and extending as far as the deflection mirror 30a is also referred to as the input beam path 26-2 of the second optical resonator 18-2. The portion of the Gaussian beam incident on the measurement target 16-2 represents the aforementioned measurement beam 28-2.

The optical resonators 18-1 and 18-2 are arranged such that their input beam paths 26-1 and 26-2 are arranged parallel to each other or deviate from the parallel arrangement by a maximum of 10°. On account of the configuration of the second optical resonator 18-2 with the deflection mirror 30a, the optical resonators 18-1 and 18-2 are configured to radiate the two measurement beams 28-1 and 28-2 on the corresponding measurement target 16-1 and 16-2, respectively, from different directions, i.e. from the positive x-direction and negative y-direction in the concrete embodiment according to FIG. 1. In the embodiment shown, the directions of the two measurement beams 28-1 and 28-2 deviate from each other by 90°; in general, they deviate by at least 30°, such as by at least 80°.

In the embodiment depicted in FIG. 1, the two measurement beams 28-1 and 28-2 are aligned such that their extensions through the respective measurement target 16-1 and 16-2 intersect each other, i.e. the virtual beam paths of the measurement beams 28-1 and 28-2 have at least one overlap. In the depicted embodiment, the measurement beams 28-1 and 28-2 are even aligned so precisely at each other that respective beam axes 29-1 and 29-2 of the measurement beams 28-1 and 28-2, which are also referred to as measurement axes of the measuring module 10, intersect at a virtual point of intersection 32.

The measuring module 10 also comprises two measurement radiation units 34-1 and 34-2, which are each connected to a waveguide 36 in the form of an optical fiber for supplying the two resonators 18-1 and 18-2 with the respective measurement radiation 24-1 and 24-2. Using a respective input coupling lens 38, the measurement radiation 24-1 and 24-2 generated by the respective measurement radiation unit 34-1 and 34-2 is input coupled into the respective optical resonator 18-1 and 18-2 through the input coupling mirror 22-1 and 22-2. Furthermore, the measurement radiation 24-1 and 24-2 leaving the respective optical resonator 18-1 and 18-2 via the respective input coupling lens 38 and the respective waveguide 36 is fed back into the relevant measurement radiation unit 34-1 and 34-2 and evaluated there. The measurement radiation units 34-1 and 34-2 are arranged outside the measuring head 12 in the embodiment according to FIG. 1. Alternatively, these may also be integrated into the measuring head 12, in which case the waveguide 36 may optionally be omitted.

The structure of the measurement radiation units 34-1 and 34-2 is described in exemplary fashion below with reference to the measurement radiation unit 34 illustrated in FIG. 5. It is based on the principle whereby a laser 40 that is tunable with regards to the optical frequency follows a frequency of the optical resonator 18-1 or 18-2 via a suitable control loop (according to the Pound-Drever-Hall method in the example illustrated), such that the length of the resonator 18-1 or 18-2 that is ultimately to be measured is encoded as a frequency of the tunable laser 40. The laser 40 serves as radiation source for the measurement radiation 24-1 or 24-2, which for example is located in the visible or infrared wavelength range.

The measurement radiation unit 34 comprises a Faraday isolator 42, an electro-optic modulator 44, a polarization-optical beam splitter 46, a quarter wave plate 48, a photodetector 50 and a low-pass filter 52. The portion of the measurement radiation 24-1 or 24-2 that passes through the quarter wave plate 48 enters the optical resonator 18-1 or 18-2 via the waveguide 36 depicted in FIG. 1. Referring back to FIG. 5, for the purpose of frequency measurement, a portion of the measurement radiation 24 emitted by the tunable laser 40 is output coupled via a beam splitter 54 and fed to a frequency measuring device in the form of an analyzer 56 for frequency measurement. The actual frequency measurement in the analyzer 56 may be effected for example by way of the comparison with a frequency reference, e.g. an fs frequency comb of a femtosecond laser. The measurement radiation 24 leaving the optical resonator 18-1 or 18-2 again via the input coupling mirror 22-1 or 22-2 according to FIG. 1 re-enters the measurement radiation unit 34 via the relevant optical waveguide 36 and is captured by the photodetector 50. For further details regarding the functionality of the measurement radiation unit 34, reference is made to DE 10 2018 208 147 A1. The measured frequency of the respective measurement radiation 24-1 or 24-2 has a functional relationship with the length of the relevant optical resonator 18-1 or 18-2 and hence with the distance between the relevant input coupling mirror 22-1 and 22-2 and the relevant measurement target 16-1 or 16-2. From the measured optical frequencies of the measurement radiations 24-1 and 24-2, the measuring module 10 thus calculates the respective distances of the measurement targets 16-1 and 16-2 from the relevant input coupling mirrors 22-1 and 22-2 and hence the position of the measurement object in two coordinate directions.

FIG. 6 shows a simplified illustration of the aforementioned microlithographic projection exposure apparatus 100 having the mirror 126, which serves as component for the measurement carried out by the measuring module 10. As illustrated in FIG. 7, the mirror 126 is mounted on a support structure 138, for instance in the form of a reference frame or a housing of the projection lens 116 of the projection exposure apparatus 100.

The projection exposure apparatus 100 according to FIG. 6 is designed to operate with EUV exposure radiation 101. In this text, EUV radiation should be understood to mean electromagnetic radiation at a wavelength of less than 100 nm, such as a wavelength of approximately 13.5 nm or approximately 6.8 nm. However, the present disclosure is not limited to application in such an apparatus but may also be implemented when measuring projection exposure apparatuses with different operating wavelengths, for example operating wavelengths in the VUV or DUV range. In further applications, the disclosure can also be realized in a different microlithographic optical system, for instance a mask inspection apparatus or a wafer inspection apparatus. The projection exposure apparatus 100 comprises an exposure beam path 117 in which the exposure radiation 101 is guided through an illumination optics unit 105 and a projection lens 116.

According to the exemplary embodiment of FIG. 6, the illumination optics unit 105 comprises a field facet mirror 102, a pupil facet mirror 104 and two telescopic mirrors 110 and 112. The exposure radiation 101, which is generated by an EUV radiation source comprising a plasma radiation source 106 and a collector mirror 108, is initially steered onto the field facet mirror 102 and, from there, onto the pupil facet mirror 104. The first telescopic mirror 110 and the second telescopic mirror 112 are arranged downstream of the pupil facet mirror 104 in the beam path. Arranged downstream in the beam path is a deflection mirror 114, which steers the radiation incident thereon onto an object field in the object plane of the projection lens 116, which comprises six mirrors 118, 120, 122, 124, 126 and 128.

A reflective structure-bearing mask 130 on a mask stage 132 is arranged at the location of the object carrier, the mask being imaged by way of the projection lens 116 into an image plane, in which a substrate 134 in the form of a wafer, coated with a radiation-sensitive layer (photoresist), is located on a wafer stage 136.

As illustrated in FIG. 7 and in accordance with an embodiment for monitoring the position and/or alignment of the mirror 126 with respect to the support structure 138 during operation, i.e. in situ, the positions of three measurement objects 14A, 14B and 14C that are arranged on a back side 146 of the mirror 126 opposite the mirror surface 144 are ascertained, in each case in two measurement coordinates, using three measuring modules 10 according to FIG. 1, referred to here as measuring modules 10A, 10B and 10C. The measurement coordinates are ascertained by determining the distances ax and ay in the coordinate system of measuring module 10.

FIG. 2 shows a plan view of the back side 146 of the mirror 126 with the measurement objects 14A, 14B and 14C arranged thereon. The respective arrangement of the measuring modules 10A, 10B and 10C in connection with the respective associated measurement object 14A, 14B and 14C is shown in FIG. 3 in a sectional view along the sectional lines I-I′, II-II′ and III-III′. The measuring modules 10A, 10B and 10C form a measuring arrangement.

Accordingly, the distances ax1 and ay1 measured by the measuring module 10A represent a position deviation of the measurement object 14A from a target position in the coordinate directions Y and Z of the mirror coordinate system. Furthermore, the distances ax2 and ay2 measured by the measuring module 10B represent a position deviation of the measurement object 14B from a target position in the coordinate directions Y and Z of the mirror coordinate system. Finally, the distances ax3 and ay3 measured by the measuring module 10C represent a position deviation of the measurement object 14C from a target position in the coordinate directions X and Z of the mirror coordinate system.

The respective points of intersection 10A, 10B and 10C of beam axes 29-1 and 29-2 of measuring modules 32A, 32B and 32A are referred to below as the respective measurement locations on the mirror 126, which are assigned to the corresponding measurement targets 16-1 and 16-2. These locations are each located in the interior of the measurement objects 14A, 14B and 14C and, on account of the arrangement of the measurement objects 14A, 14B and 14C on the back side 146 of the mirror 126, are referred to as measurement locations on the mirror 126 that are assigned to the measurement objects 14A, 14B and 14C. The measurement locations in the form of the points of intersection 32A, 32B and 32C define a measurement plane that extends parallel to the XY-coordinate plane. The measurement beams 28-2 of the measuring modules 10A, 10B and 10C are each oriented in the y-direction and hence transversely to the measurement plane. The measurement beams 28-1 of the measuring modules 10A, 10B and 10C are each oriented parallel to the measurement plane. The measurement beams 28-1 of the measuring modules 10A and 10B have the same direction (parallel to the Y-coordinate axis), while the measurement beam 28-1 of the measuring module 10C has a differently oriented direction (parallel to the X-coordinate axis).

In an evaluation device not shown in drawing, the measured distances ax1, ay1, ax2, ay2, ax3 and ay3 and the distance L between the beam axes 29-1 of measuring modules 10A and 10B, the distance Ha between an optical center 140 of the mirror surface 144 and a connecting line 142 between the beam axes 29-2 of the measuring modules 10A and 10B and the distance Hb between the optical center 140 and the beam axis 29-2 of the third measuring module 10C are used to determine the coordinates of all rigid body degrees of freedom, i.e. the X-, Y- and Z-coordinates and the tilt values Tx, Ty and Tz (tilts with respect to X-, Y- or Z-coordinate axis), of a misalignment of the mirror 126, as follows:

$$X = ax 3 - {Tz}^{*} Hb$$

$$Y = ( ax 1 - ax 2 ) / 2$$

$$Z = ( - ay 1 - ay 2 ) / 2 - {Ha}^{*} Tx$$

$$Tx = ( ay 3 + ( - ay 1 - ay 2 ) / 2 ) / ( Hb + Ha )$$

$$Ty = ( - ay 2 + ay 1 ) / L$$

$$Tz = ( ax 1 - ax 2 ) / L$$

The effect of the misalignment or mispositioning of the mirror 526, determined thereby, on the imaging quality of the projection exposure apparatus 100 is corrected by compensatory measures, such as positional changes of another mirror in the projection lens 116, a combination of other mirrors in the projection lens 116, the mask table 132 and/or the wafer stage 136. As an alternative to that or in addition, the positioning of the mirror in relation to the support structure may also be corrected using optionally provided adjustment devices.

FIG. 2 illustrates the mirror 126 in an embodiment variant in which a coolant inlet 58 and a coolant return 60 are provided for cooling the mirror 126. In its interior or on its back side 146, the mirror comprises cooling lines, through which the cooling fluid flows when the mirror 126 is cooled. Alternatively, cooling fluid may also flow directly onto the back side 146. The aforementioned misalignment or mispositioning of the mirror, which is determined via the measuring modules 10A, 10B and 10C, may be traced back to the mechanisms listed below. Firstly, mounting the mirror 126 on the support structure 138 configured as a reference frame is not implemented completely rigidly according to an embodiment variant, in order to minimize a deformation of the mirror surface 144 resulting from the mounting process. However, this may cause the mirror 126 to be misaligned on account of fluctuating fluid pressure in the cooling lines or on account of acoustic waves propagating through the cooling fluid. In turn, a misalignment of the mirror 126 may lead to lateral imaging errors of the projection exposure apparatus 100 (also referred to as “line-of-sight errors”). These errors can be eliminated by measuring the position using measuring modules 10A, 10B and 10C and by the corresponding aforementioned compensation or correction measures.

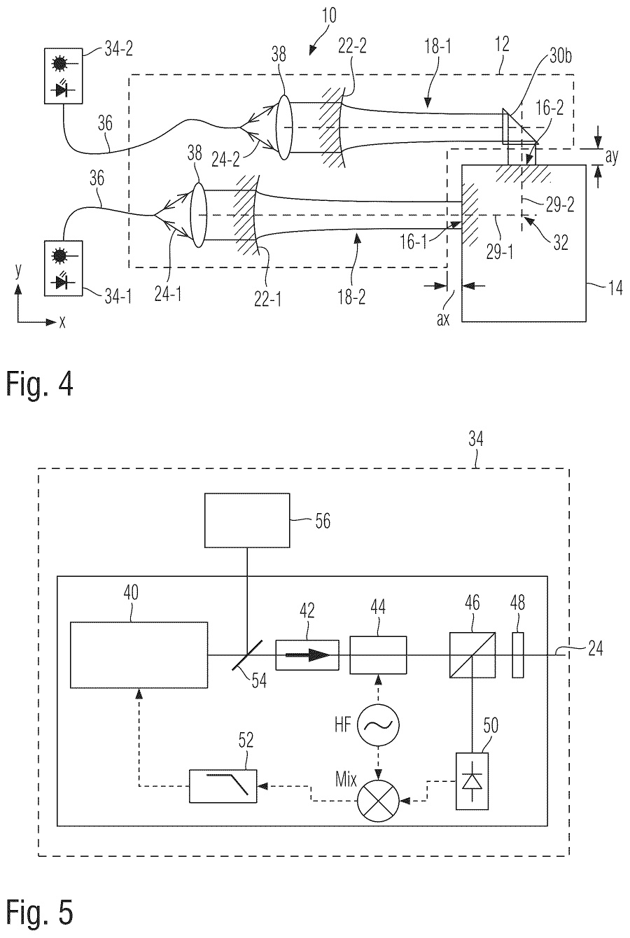

FIG. 4 depicts a further embodiment of a measuring module 10 for determining the position of a component in a microlithographic optical system. This embodiment differs from the embodiment according to FIG. 1 merely in that the deflection element is embodied as a deflection prism 30b rather than a deflection mirror. In this case, the measurement radiation 24 is deflected by total-internal reflection at the transition between the prism glass and the surroundings. Hence, no intensity losses arise in this embodiment.

The above description of exemplary embodiments, embodiments or variant embodiments should be understood to be by way of example. The disclosure effected thereby firstly enables a person skilled in the art to understand the present disclosure and the features associated therewith, and secondly encompasses alterations and modifications of the described structures and methods that are also obvious in the understanding of a person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10, 10A, 10B, 10C Measuring module
12 Measuring head
14, 14A, 14B, 14C Measurement object
16-1 First measurement target
16-2 Second measurement target
18-1 First optical resonator
18-2 Second optical resonator
20-1 First resonator cavity
20-2 Second resonator cavity
22-1 Input coupling mirror
22-2 Input coupling mirror
24-1 First measurement radiation
24-2 Second measurement radiation
26-1 Input beam path
26-2 Input beam path
28-1 First measurement beam
28-2 Second measurement beam
29-1 Beam axis of the first measurement beam
29-2 Beam axis of the second measurement beam
30a Deflection mirror
30b Deflection prism
32 Virtual point of intersection
34-1 First measurement radiation unit
34-2 Second measurement radiation unit
36 Waveguide
38 Input coupling lens
40 Laser
42 Faraday isolator
44 Electro-optic modulator
46 Polarization-optical beam splitter
48 Quarter wave plate
50 Photodetector
52 Low-pass filter
54 Beam splitter
56 Analyzer
58 Coolant inlet
60 Coolant return
100 Microlithographic projection exposure apparatus
101 Exposure radiation
102 Field facet mirror
104 Pupil facet mirror
105 Illumination optics unit
106 Plasma light source
108 Collector mirror
110 First telescopic mirror
112 Second telescopic mirror
114 Deflection mirror
116 Projection lens
117 Exposure beam path
118, 120, 122, 124, 128 Mirrors of the projection lens
126 Mirror of the projection lens, serving as component to be measured
130 Mask
132 Mask stage
134 Substrate
136 Wafer stage
138 Support structure
140 Optical center
142 Connecting line
144 Mirror surface
146 Back side

What is claimed is:

1. A measuring module configured to determine a position of a component in a microlithographic optical system, the measuring module comprising:
a first optical resonator for distance measurement by irradiating a first measurement target associated with the component with a first measurement beam having a first direction; and
a second optical resonator for distance measurement by irradiating a second measurement target associated with the component with a second measurement beam having a second direction different from the first direction.

2. The measuring module of claim 1, wherein the first and second measurement targets are differently oriented portions of a contiguous measurement object.

3. The measuring module of claim 1, wherein the first measurement target comprises a resonator mirror of the first optical resonator.

4. The measuring module of claim 1, wherein the first optical resonator comprises a deflection element configured to change the direction of the first beam path within the first optical resonator.

5. The measuring module of claim 4, wherein the change of direction is in an angular range between 30° and 150°.

6. The measuring module of claim 4, wherein the deflection element is configured to deflect the measurement radiation from an input beam path originating from an input coupling mirror of the first optical resonator into the first measurement beam.

7. The measuring module of claim 6, wherein respective input beam paths of the two optical resonators, which originate from a respective input coupling mirror of the relevant resonator, are parallel to each other or deviate from the parallel arrangement by no more than 10°.

8. The measuring module of claim 1, further comprising first and second waveguides, wherein the first waveguide is configured to supply measurement radiation to the first optical resonator, and the second waveguide is configured to supply measurement radiation to the second optical resonator.

9. The measuring module of claim 1, wherein the optical system is a microlithographic projection exposure apparatus.

10. The measuring module of claim 1, wherein the measuring module is configured to perform a separate frequency-based length measurement on each of the two optical resonators.

11. The measuring module of claim 1, wherein the first and second measurement beams are aligned so that their extensions through the respective measurement target intersect each other.

12. A measuring arrangement configured to determine a position of a component in a microlithographic optical system, the measuring arrangement comprising:
at least three measuring modules according to claim 1,
wherein the measurement targets associated with each respective measuring module are arranged on a respective measurement object and the measurement objects are assigned to different measurement locations on the component.

13. The measurement arrangement of claim 12, wherein:
the measurement locations assigned to the measurement objects define a measurement plane;
at least one of the measurement beams generated by the measuring modules is oriented transversely to the measurement plane; and
at least two of the measurement beams generated by the measuring modules have different directions, each oriented substantially parallel to the measurement plane.

14. The measurement arrangement of claim 12, wherein the measurement locations assigned to the measurement objects define a measurement plane, and at least three of the measurement beams generated by the measuring modules are oriented transversely to the measurement plane.

15. A microlithographic optical system, comprising:
an object; and
a measuring module according to claim 1.

16. A microlithographic optical system, comprising:
a measuring arrangement configured to determine a position of a component in a microlithographic optical system, the measuring arrangement comprising at least three measuring modules according to claim 1,
wherein:
the measurement targets associated with each respective measuring module are arranged on a respective measurement object and the measurement objects are assigned to different measurement locations on the component; and
the microlithographic optical system is a microlithographic projection exposure apparatus.

17. The microlithographic optical system of claim 14, wherein:
the component comprises a mirror in an exposure beam path of the projection exposure apparatus; and
the projection exposure apparatus furthermore comprises a cooling device for the mirror by means of flowing cooling liquid, and the measuring module is configured to measure vibrations of the mirror generated by the cooling process.

18. A measuring module configured to determine a position of the component in the microlithographic optical system, the measuring module comprising:
an optical resonator for distance measurement by irradiating a measurement target associated with the component in the microlithographic optical system,
wherein the optical resonator comprises a deflection element configured to change a direction of a beam path within the optical resonator by an angle between 30° and 150°.

19. A microlithographic optical system, comprising:
an object; and
a measuring module according to claim 18.

20. A microlithographic optical system, comprising:
a measuring arrangement configured to determine a position of a component in a microlithographic optical system, the measuring arrangement comprising at least three measuring modules according to claim 18,
wherein:
the measurement targets associated with each respective measuring module are arranged on a respective measurement object and the measurement objects are assigned to different measurement locations on the component; and
the microlithographic optical system is a microlithographic projection exposure apparatus.
